(19) United States
(12) Patent Application Publication
(10) Pub. No.: US 2024/0352950 A1
(43) Pub. Date: Oct. 24, 2024

(54) INTEGRATED VALVE, AND METHOD FOR DESIGNING AND MANUFACTURING VALVE BODY OF INTEGRATED VALVE

(71) Applicants: JIANGSU XCMG CONSTRUCTION MACHINERY RESEARCH INSTITUTE LTD.; XCMG FIRE-FIGHTING SAFETY EQUIPMENT CO., LTD.

(72) Inventors: Yajie LIU, Xuzhou (CN); Bing HE, Xuzhou (CN); Fuxiang BO, Xuzhou (CN); Lei XU, Xuzhou (CN)

(21) Appl. No.: 18/035,201

(22) PCT Filed: Apr. 10, 2023
(86) PCT No.: PCT/CN2023/087251

§ 371 Date: May 3, 2023

(30) Foreign Application Priority Data
Feb. 24, 2023 (CN) 202310161212.7

(51) Int. Cl. F15B 13/02; G06F 30/23

(52) U.S. Cl. CPC F15B 13/02; G06F 30/23

(57) ABSTRACT

An integrated valve is made by a method for designing and manufacturing a valve body of the integrated valve. The method for designing the valve body of the integrated valve includes: determining an internal flow channel structure of a valve body model of the integrated valve according to a hydraulic function implemented by the integrated valve; determining a position and a size of respective mounting structures, matched with the external devices, in the valve body model; determining a work structure of the valve body model according to the internal flow channel structure, and the position and the size of respective mounting structures; determining an internal connection plane of the valve body model, and determining an internal supporting table; and determining an external shell of the valve body model, and connecting the external shell with the work structure and the internal supporting table.

### CROSS-REFERENCE TO RELATED APPLICATIONS

The application is based upon and claims priority to Chinese Patent Application No. 202310161212.7, filed on Feb. 24, 2023, the disclosure of which are incorporated herein by reference.

### TECHNICAL FIELD

The present disclosure relates to the field of a hydraulic technology, and in particular to an integrated valve, and a method for designing and manufacturing a valve body of the integrated valve.

### BACKGROUND

A hydraulic valve is an automatic component using pressure oil for operation. The hydraulic valve is usually used in combination with an electromagnetic distributing valve, and is controlled by pressure oil of the distributing valve. The hydraulic valve can be used to remotely control on and off of oil, gas and water pipeline systems of a hydropower station, and is often applied to oil paths such as clamping, control and lubricating. The hydraulic valve includes a direct-acting type and a pilot-operated type, and can be used to control a liquid pressure, a liquid flow and a liquid direction in hydraulic transmission.

A hydraulic valve body manufactured by a traditional design and machining method is usually an integral forged piece, where the machining includes blanking, forging, heat treatment, shape milling, mounting hole drilling, mounting surface grinding, boring, fitting, galvanizing and the like. The valve body is provided with a mounting hole of the valve body, a mounting and fixing hole and an oil channel of related plug-ins, and a process hole and a positioning pinhole to be processed in the oil channel. Limited by the machining method, all the hole positions are arranged horizontally or vertically, and inclined holes are avoided as far as possible.

The hydraulic valve body manufactured by the traditional design and machining method generally has the following problems:

1) the valve body is manufactured by a forging method, so it is difficult to avoid air hole, sand hole or interlayer phenomenon, and the qualification rate of products and using safety cannot be ensured.

2) In the process of valve body processing, it will go through pretreatment, machining, deburring, cleaning and other stages, with the technical problems of cumbersome clamping, difficult of geometric tolerance, high requirement on roughness and the like.

3) Limited by the traditional manufacturing method, the internal flow channel of the valve body is arranged horizontally or vertically, a large number of process holes are present. To avoid interference in flow channel machining, the valve body has a complicated structure, design redundancy and high leakage risk.

4) The valve body is heavy and bulky. For structures with weight requirements, the valve body has a high weight ratio and a high volume ratio, and is unfavorable for the arrangement of various structures and the implementation of various functions.

### SUMMARY

Embodiments of the present disclosure provide an integrated valve, and a method for designing and manufacturing a valve body of the integrated valve, so that the weight of the valve body is reduced while the quality of the integrated valve is improved.

According to one aspect of the present disclosure, a method for designing a valve body of an integrated valve is provided and includes: determining an internal flow channel structure of a valve body model of the integrated valve according to a hydraulic function implemented by the integrated valve; according to a position and a connection mode of respective external devices connected to the integrated valve, determining a position and a size of respective mounting structures, matched with the external devices, in the valve body model; determining a work structure of the valve body model according to the internal flow channel structure, and the position and the size of respective mounting structures; determining an internal connection plane of the valve body model according to center lines of respective flow channels in the internal flow channel structure, and determining an internal supporting table for supporting the work structure according to the internal connection plane; and determining an external shell of the valve body model, and connecting the external shell with the work structure and the internal supporting table.

In some embodiments, the design method further includes: when determining the internal flow channel structure, performing transition process on the center lines of respective flow channels in the internal flow channel structure according to a B-spline curve.

In some embodiments, the step of determining a work structure of the valve body model according to the internal flow channel structure, and the position and the size of respective mounting structures includes: according to the internal flow channel structure, and the position and the size of respective mounting structures, setting a preset thickness for the internal flow channel structure and respective mounting structures in the valve body to form the work structure of the valve body model.

In some embodiments, the step of forming the work structure of the valve body model includes: keeping a bore diameter of flow channels unchanged and setting a preset thickness for the internal flow channel structure, to form a work structure of the internal flow channel structure.

In some embodiments, the step of according to a position and a connection mode of respective external devices connected to the integrated valve, determining a position and a size of respective mounting structures matched with the external devices in the valve body model includes at least one of the followings: determining a position and a size of a valve body mounting and fixing hole in the valve body model according to a mounting position and mounting mode of the integrated valve; determining a position and a size of a shaft coupler mounting and fixing surface on the valve body model according to a connection position and size of a valve body center of the integrated valve and a shaft coupler; determining a position and a size of a motor mounting and fixing hole in the valve body model according to a connection position and size of the valve body of the integrated valve and a motor; determining a position and a size of a pump mounting and fixing hole in the valve body model according to a connection position and size of the valve body of the integrated valve and a pump; obtaining a position and a size of an oil tank mounting and fixing hole in the valve body model according to a connection position and size of the valve body of the integrated valve and an oil tank; and obtaining positions and sizes of connecting plug-ins and respective ports in the valve body model according to positions of connecting plug-ins of the valve body of the integrated valve and ports of the connecting plug-ins.

In some embodiments, the step of forming the work structure of the valve body model includes at least one of the followings: keeping a bore diameter of the valve body mounting and fixing hole unchanged and setting a preset thickness for the valve body mounting and fixing hole, to form a work structure of the valve body mounting and fixing hole; keeping a connection position and size of the shaft coupler mounting and fixing surface unchanged and setting a preset thickness for the shaft coupler mounting and fixing surface, to form a work structure of the shaft coupler mounting and fixing surface; keeping a bore diameter of the motor mounting and fixing hole unchanged and setting a preset thickness for the motor mounting and fixing hole, to form a work structure of the motor mounting and fixing hole; keeping a bore diameter of the pump mounting and fixing hole unchanged and setting a preset thickness for the pump mounting and fixing hole, to form a work structure of the pump mounting and fixing hole; keeping a bore diameter of the oil tank mounting and fixing hole unchanged and setting a preset thickness for the oil tank mounting and fixing hole, to form a work structure of the oil tank mounting and fixing hole; and keeping a connection position and size of the connecting plug-ins unchanged and setting a preset thickness for ports of the connecting plug-ins, to form a work structure of the connecting plug-ins and the ports of the connecting plug-ins.

In some embodiments, the step of determining an internal connection plane of the valve body model according to center lines of respective flow channels in the internal flow channel structure includes: setting a plane in which most center lines of the flow channels are distributed as the internal connection plane.

In some embodiments, the step of determining an internal supporting table for supporting the work structure according to the internal connection plane includes: setting a preset thickness for the internal connection plane to form the internal supporting table, and fixedly connecting the internal supporting table with parts, located on two sides of the internal connection plane, of the work structure.

In some embodiments, the design method further includes: when determining the external shell, arranging a lattice structure or a crystal lattice structure on a local position of the external shell.

In some embodiments, the design method further includes: after forming the work structure, according to a protruding length or a protruding angle of a cantilever part of the work structure relative to the external shell, arranging a reinforcing rib on the cantilever part.

In some embodiments, the design method further includes: performing finite element simulation and verification on the valve body model, and performing iteratively optimization on a stress concentration area of the valve body model.

In some embodiments, the design method further includes: setting identification information on a surface of the valve body model.

According to one aspect of the present disclosure, a method for manufacturing a valve body of an integrated valve is provided and includes: obtaining a valve body model designed by the above-mentioned method; and machining and manufacturing the valve body model by an additive manufacturing method to form the valve body of the integrated valve.

According to one aspect of the present disclosure, an integrated valve is provided and includes: a valve body, manufactured by the above method.

In some embodiments, the valve body includes: an external shell; a work structure of an internal flow channel structure, at least partially arranged in the external shell and fixedly connected to the external shell; work structures of respective mounting structures matched with the external devices, at least partially arranged in the external shell and fixedly connected to the external shell; and an internal supporting table, arranged in the external shell, and fixedly connected to at least part of the work structures of respective mounting structures, the external shell and at least part of the work structure of the internal flow channel structure.

In some embodiments, the valve body further includes: a reinforcing rib, connected to at least one of the work structures of respective mounting structures, the external shell and the work structure of the internal flow channel structure.

Therefore, according to the embodiments of the present disclosure, when the valve body of the integrated valve is designed, the internal flow channel structure and the mounting structure of the valve body model are determined respectively according to the hydraulic function implemented by the integrated valve and the position and connection mode of the external device connected to the integrated valve, the work structure of the valve body model is determined according to the internal flow channel structure and the mounting structure, and then the work structure of the valve body model is connected and supported by the determined internal supporting table and the external shell. According to this design method, for the integrated valve required to implement the complicated hydraulic function, the work structure can be formed pertinently according to the connection relationship of the integrated valve and the internal flow channels, and the work structure is connected and supported by the internal supporting table and the external shell, so that the valve body can be manufactured by an additive manufacturing method, the weight of the valve body is reduced by reducing the redundant part of the non-work structure, lightweight is achieved, the defects of air holes, sand holes and interlayers caused by the traditional manufacturing method are avoided, and the quality of the integrated valve is improved.

### BRIEF DESCRIPTION OF THE DRAWINGS

The accompanying drawings, which constitute a part of this description, describe the embodiments of the present disclosure and, together with the description, serve to explain the principles of the present disclosure.

Referring to the accompanying drawings and according to the following detailed description, the present disclosure may be more clearly understood, wherein

FIG. 1 is a schematic flowchart of some embodiments according to a method for designing a valve body of an integrated valve provided by the present disclosure;

FIG. 2 is a schematic diagram of an internal flow channel structure and part of mounting structures in a valve body model according to a method for designing a valve body of an integrated valve provided by the present disclosure; and

FIGS. 3 to 6 are respectively structural schematic diagrams of a valve body from different perspectives in some embodiments according to an integrated valve provided by the present disclosure.

It should be understood that the dimensions of each part shown in the accompanying drawings are not drawn according to the actual proportional relationship. In addition, the same or similar reference numerals represent the same or similar components.

### DETAILED DESCRIPTION

Exemplary embodiments of the present disclosure are described in detail hereinafter with reference to the accompanying drawings. The description of the exemplary embodiments is merely illustrative and never constitutes any limitation to the present disclosure and application or use thereof. The present disclosure may be implemented in many different forms and is not limited to the embodiments described herein. The embodiments are provided to make the present disclosure thorough and complete and to fully express the scope of the present disclosure to those skilled in the art. It should be noted that unless otherwise specified, relative arrangement of parts and steps, composition of materials, numerical expressions and numerical values illustrated in the embodiments should be explained to be exemplary only, but not be construed as limitations.

The “first”, “second” and other similar words do not denote any order, number or importance, but are merely intended to distinguish different parts. The “include” or “comprise” and other similar words mean that elements appearing before the word cover elements listed after the word, but do not exclude the possibility of covering other elements. “Up”, “down”, “left”, “right”, or the like is only used to indicate a relative location relationship. When an absolute location of a described object changes, the relative location relationship may also change accordingly.

In the present disclosure, when it is described that a specific device is positioned between a first device and a second device, an intermediate device may or may not be present between the specific device and the first device or the second device. When it is described that the specific device is connected to other devices, the specific device may be directly connected to the other device and may not have the intermediate device, and may not be directly connected to the other device and may have the intermediate device.

All terms used in the present disclosure (including technical terms or scientific terms) have the same meaning as those understood by those of ordinary skill in the technical field which the present disclosure belongs to, unless otherwise specifically defined. It should be understood that terms defined in, for example, a general dictionary should be interpreted as having meanings consistent with the meanings in the context of the related art, and should not be interpreted in an idealized or extremely formal sense unless explicitly defined herein.

Technologies, methods and equipment known to those of ordinary skill in the related field may not be discussed in detail, but, where appropriate, the technologies, methods and equipment should be regarded as a part of the specification.

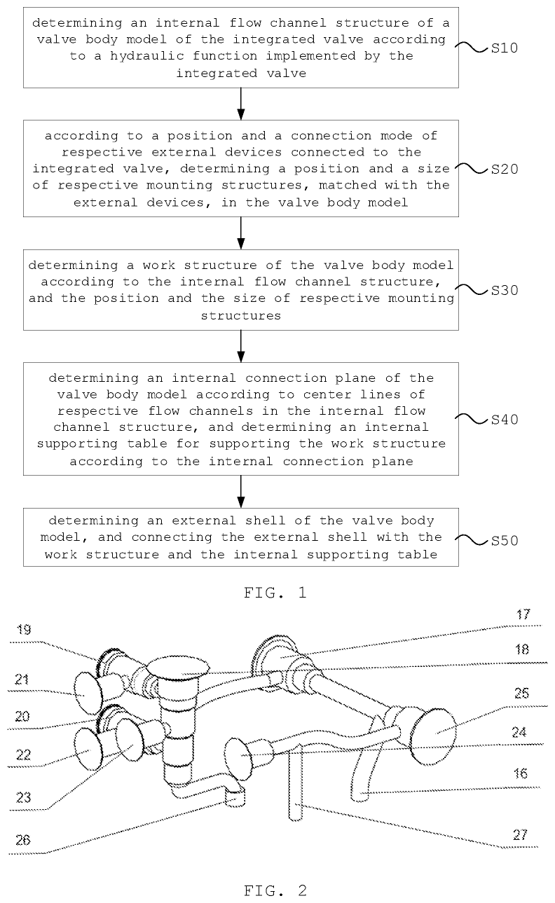

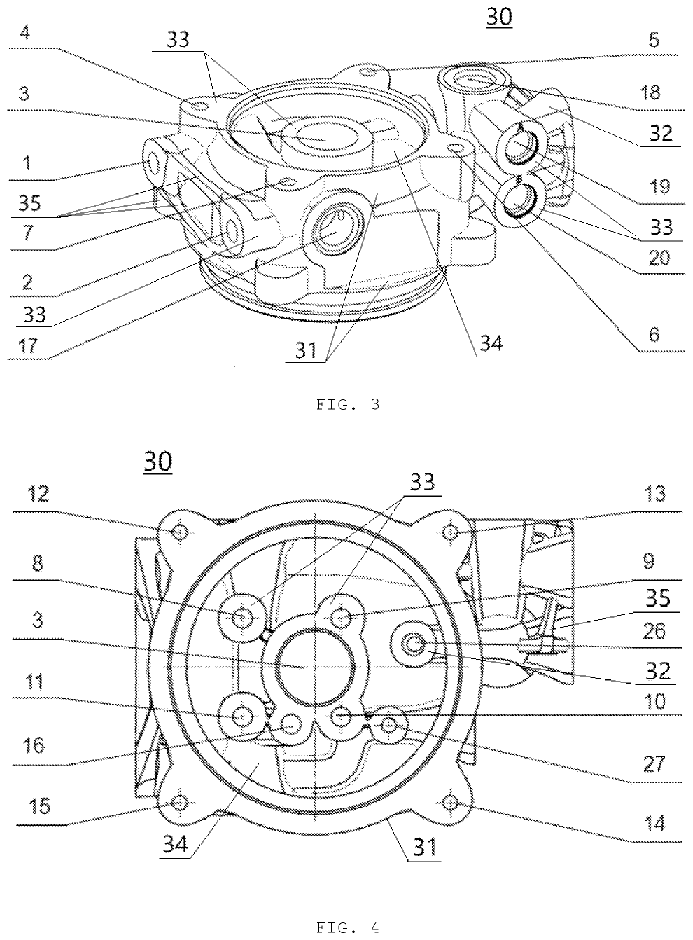

FIG. 1 is a schematic flowchart of some embodiments according to a method for designing a valve body of an integrated valve provided by the present disclosure. FIG. 2 is a schematic diagram of an internal flow channel structure of a valve body model according to a method for designing a valve body of an integrated valve provided by the present disclosure. Referring to FIG. 1 and FIG. 2, embodiments of the present disclosure provide a method for designing a valve body of an integrated valve. The method includes step S10 to step S50. The performing order of step S10 and step S20 may be: step S10 is performed and then step S20 is performed, or step 20 is performed and then step S10 is performed, or step S10 and step S20 are performed at the same time. In addition, the integrated valve here may be an integrated valve for a leveling hydraulic system of an aerial ladder fire truck, or may be a suspension valve of a high-speed engineering truck or an integrated valve for adjusting a vehicle posture of an unmanned operation platform.

In step S10, an internal flow channel structure of a valve body model of the integrated valve is determined according to a hydraulic function implemented by the integrated valve. The internal flow channel structure here reflects a flow channel of hydraulic fluid (such as hydraulic oil) in the integrated valve. The valve body model of the integrated valve may be a three-dimensional valve body model generated by computer software based on a hydraulic schematic diagram corresponding to the hydraulic function.

The integrated valve, for implementing two leveling methods of electrohydraulic control and footboard control, in the leveling hydraulic system of the aerial ladder fire truck is taken as an example. The valve body of the integrated valve is fixed at the bottom of an aerial work platform of the aerial ladder fire truck. The leveling hydraulic system can implement two leveling methods of electrohydraulic control and footboard control. When electrohydraulic control goes wrong, emergency substitution can be realized through footboard control.

Referring to FIG. 2, the internal flow channel structure includes 12 ports and flow channels connecting different ports. A port 16 is an oil inlet, a port 17 is connected to a one-way valve in the leveling hydraulic system of the aerial ladder fire truck, and a port 18 is connected to an electromagnetic directional valve in the leveling hydraulic system of the aerial ladder fire truck.

A port 19 is connected to a shuttle valve in the leveling hydraulic system of the aerial ladder fire truck and is set as a first working interface (that is, an interface A), and a port 20 is connected to the shuttle valve and is set as a second working interface (that is, an interface B). A port 21 is set as a first load-sensitive interface (that is, an interface LS1), and a port 22 is set as a second load-sensitive interface (that is, an interface LS2).

A port 23 is set as a pressure-measuring interface M, a port 24 is set as an oil return port T, a port 25 is connected to an overflow valve, a port 26 is an electrohydraulic control oil return port and directly communicates with an oil tank, and a port 27 is a footboard control oil return port and directly communicates with the oil tank.

In S10, when the internal flow channel structure is determined, transition process is performed on the center lines of respective flow channels in the internal flow channel structure according to a B-spline curve. The flow channel subjected to the transition process of the B-spline curve can effectively reduce a large number of process hole structures required for the traditional design and manufacturing, effectively solve the technical problem of large pressure loss in the traditional design, effectively reduce the leakage risk in the use process of the valve body, and reduce the pressure loss by 56.76%. According to the characteristic of the additive manufacturing process such as metal 3D printing that any complicated shape can be manufactured, the performance of the integrated valve can be effectively improved.

In step S20, according to a position and a connection mode of respective external devices connected to the integrated valve, a position and a size of respective mounting structures, matched with the external devices, in the valve body model are determined. Here, when the integrated valve is arranged in the hydraulic system, the integrated valve is required to be connected to a plurality of external devices mechanically or through a hydraulic flow path.

The external devices may include: a mounting base structure for mounting the integrated valve, and a connecting plug-in inserted and fixed in a port on the integrated valve. The connecting plug-in may be a valve for implementing different functions, such as a one-way valve, an electromagnetic directional valve, a shuttle valve or an overflow valve. For an integrated structure in which a motor, a pump and an oil tank are arranged on the integrated valve, the external device may include a motor, a pump, an oil tank, and a shaft coupler connecting the motor and the pump.

For example, step S20 may include at least one of the followings: determining a position and a size of a valve body mounting and fixing hole in the valve body model according to a mounting position and mounting mode of the integrated valve; determining a position and a size of a shaft coupler mounting and fixing surface on the valve body model according to a connection position and size of a valve body center of the integrated valve and a shaft coupler; determining a position and a size of a motor mounting and fixing hole in the valve body model according to a connection position and size of the valve body of the integrated valve and a motor; determining a position and a size of a pump mounting and fixing hole in the valve body model according to a connection position and size of the valve body of the integrated valve and a pump; obtaining a position and a size of an oil tank mounting and fixing hole in the valve body model according to a connection position and size of the valve body of the integrated valve and an oil tank; and obtaining positions and sizes of connecting plug-ins and respective ports in the valve body model according to positions of connecting plug-ins of the valve body of the integrated valve and ports of the connecting plug-ins.

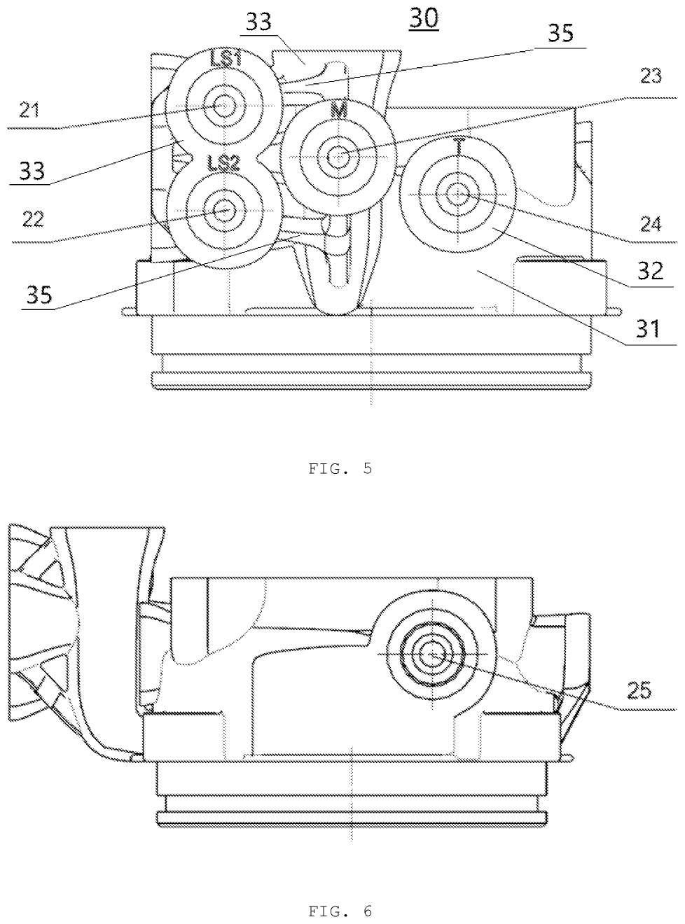

FIGS. 3 to 6 are respectively structural schematic diagrams of a valve body from different perspectives in some embodiments according to an integrated valve provided by the present disclosure. Taking a valve body 30 of the integrated valve shown in FIGS. 3 to 6 as an example, a valve body center 3 of the valve body 30 is provided with a center hole at which a shaft coupler may be arranged. The shaft coupler is respectively connected to the motor and the pump at two ends of the center hole in the center hole. The motor is arranged at one end of the valve body 30 through mounting and fixing holes 4, 5, 6 and 7; and the pump is arranged at the other end of the valve body 30 through mounting and fixing holes 8, 9, 10 and 11. The oil tank and the pump are on the same side, and are arranged on the valve body 30 through mounting and fixing holes 12, 13, 14 and 15. A valve body model, corresponding to the valve body 30, in a computer may also be represented by FIGS. 3 to 6.

In step S30, a work structure of the valve body model is determined according to the internal flow channel structure, and the position and the size of respective mounting structures. The work structure of the valve body model here refers to a structural part that can be applied to the actual physical environment in the valve body model to implement a specified function and corresponds to a physical structural part for implementing a specified function in the manufactured valve body.

In the valve body model, respective flow channels and port in the internal flow channel structure may be a non-entity part surrounded by a wall surface with a wall thickness of 0 or a set value in the computer. To make the internal flow channel structure meet the requirement during practical work, for example, meet the pressure requirement, a work structure of the internal flow channel structure is required to be formed according to the internal flow channel structure.

In some embodiments, according to the internal flow channel structure, and the position and the size of respective mounting structures, a preset thickness may be set for the internal flow channel structure and respective mounting structures in the valve body to form the work structure of the valve body model. The preset thickness here is equivalent to a wall thickness of the flow channel or port. A larger wall thickness size can bear larger hydraulic pressure, and a smaller wall thickness size can reduce the use amount of materials and the weight of the valve body. Therefore, when the valve body is designed, a reasonable wall thickness size can be set according to actual requirements to give consideration to the performance and lightweight requirement of the valve body.

In the valve body model, the mounting structure, matched with the external device, in the valve body model may be a hole channel, for example, a mounting hole for setting a connecting piece such as a bolt, or a port for setting a connecting plug-in, or be of other structures, such as a clamping structure or a nesting structure. To obtain the work structures of the mounting structures, the size may be kept unchanged and a preset thickness meeting the work requirement is set for the mounting structures.

For example, the step of forming the work structure of the valve body model includes at least one of the followings: keeping a bore diameter of the valve body mounting and fixing hole unchanged and setting a preset thickness for the valve body mounting and fixing hole, to form a work structure of the valve body mounting and fixing hole; keeping a connection position and size of the shaft coupler mounting and fixing surface unchanged and setting a preset thickness for the shaft coupler mounting and fixing surface, to form a work structure of the shaft coupler mounting and fixing surface; keeping a bore diameter of the motor mounting and fixing hole unchanged and setting a preset thickness for the motor mounting and fixing hole, to form a work structure of the motor mounting and fixing hole; keeping a bore diameter of the pump mounting and fixing hole unchanged and setting a preset thickness for the pump mounting and fixing hole, to form a work structure of the pump mounting and fixing hole; keeping a bore diameter of the oil tank mounting and fixing hole unchanged and setting a preset thickness for the oil tank mounting and fixing hole, to form a work structure of the oil tank mounting and fixing hole; and keeping a connection position and size of the connecting plug-ins unchanged and setting a preset thickness for ports of the connecting plug-ins, to form a work structure of the connecting plug-ins and the ports of the connecting plug-ins.

In step S40, an internal connection plane of the valve body model is determined according to center lines of respective flow channels in the internal flow channel structure, and an internal supporting table for supporting the work structure is determined according to the internal connection plane. The internal connection plane may be one internal connection plane, or may be a plurality of internal connection planes. The internal connection plane may be a flat plane, or may be a cambered surface or bent surface.

In some embodiments, in step S40, the step of determining an internal connection plane of the valve body model according to center lines of respective flow channels in the internal flow channel structure may include: setting a plane in which most center lines of the flow channels are distributed as the internal connection plane. Since the internal connection plane includes the most center lines of the flow channels, the internal supporting table obtained by the internal connection plane can form a connection and supporting function with more flow channels, so that the number of the internal supporting tables is reduced, and the valve body is more lightweight.

In some embodiments, in step S40, the step of determining an internal supporting table for supporting the work structure according to the internal connection plane includes: setting a preset thickness for the internal connection plane to form the internal supporting table, and fixedly connecting the internal supporting table with parts, located on two sides of the internal connection plane, of the work structure. A single internal connection plane or a plurality of internal connection planes may be a wall surface with a wall thickness of 0 or a set value in the computer. A proper wall thickness value is set on this basis and according to actual factors such as a supporting strength of other structures, so that the stability requirement and lightweight requirement of respective parts of the valve body are met.

In step S50, an external shell of the valve body model is determined, and the external shell 1 is connected to the work structure and the internal supporting table. The external shell is connected to respective work structures and the internal supporting table, thereby reliably supporting respective work structures and the internal supporting table. The ports of part of the flow channels of the internal flow channel structure or the ports of the connecting plug-in may extend out of an outer side of the external shell, thereby facilitating connection with an external oil path.

When the external shell is set, the external shell may be locally thicker and heavier, and a lattice structure or a crystal lattice structure may be arranged on a local position of the external shell. The weight of the local position can be reduced by the lattice structure or the crystal lattice structure.

In each embodiment of the above method, for the integrated valve required to implement the complicated hydraulic function, the work structure can be formed pertinently according to the connection relationship of the integrated valve and the internal flow channels, and the work structure is connected and supported by the internal supporting table and the external shell, so that the valve body can be manufactured by an additive manufacturing method, the weight of the valve body is reduced by reducing a large number of redundant parts except for the work structure, the internal supporting table and the external shell, lightweight is achieved, the defects of air holes, sand holes and interlayers caused by the traditional manufacturing method are avoided, and the quality of the integrated valve is improved.

To keep a cantilever structure such as a port extending out of the outer side of the external shell in the valve body model, in some embodiments, after the work structure is formed, according to a protruding length or a protruding angle of the cantilever part of the work structure relative to external shell, a reinforcing rib is arranged on the cantilever part. For example, according to the situation that the protruding length of the cantilever part is greater than 20 mm or the protruding angle is less than 90°, the reinforcing rib is arranged between the cantilever part and the external shell or between the adjacent cantilever parts. The reinforcing rib may have an angle greater than or equal to 45° relative to the external shell or the adjacent cantilever parts, thereby improving the reinforcing effect.

The valve body model obtained by the above design method embodiment may be a preliminary model and may further be optimized. In some embodiments, the method may further include: performing finite element simulation and verification on the valve body model, and performing iteratively optimization on a stress concentration area of the valve body model. A fillet structure may be set for the stress concentration area to eliminate stress concentration by rounding the valve body model. Further, the simulation verification may be performed repeatedly in many iterations until the valve model meeting the requirement is obtained.

For the convenience of identifying information such as each port of the integrated valve, in some embodiments, the method further includes a step of setting identification information on a surface of the valve body model. The identification information may be a port name, for example, in FIGS. 3 to 6, an interface A representing a first working interface, an interface B representing a second working interface, an interface LS1 representing a first load-sensitive interface, an interface LS2 representing a second load-sensitive interface, a pressure-measuring interface M or an oil return port T, or may be a product identifier or a manufacturer identifier.

After the valve body model meeting the requirement is obtained, the valve body model may be machined and manufactured by an additive manufacturing method to form the valve body of the integrated valve. Referring to the method embodiment for designing the valve body of the integrated valve, embodiments of the present disclosure further provide a method for manufacturing a valve body of an integrated valve, including: obtaining a valve body model designed by the method of any one of the above embodiments; and machining and manufacturing the valve body model by an additive manufacturing method to form the valve body of the integrated valve.

The lightweight valve body is machined and manufactured by an additive manufacturing technology instead of a traditional machining technology, so that the performance of the integrated valve can be improved, and the weight and the volume can be effectively reduced. This has a great influence on the aerial platform working machine with a weight requirement, which can effectively improve the loading capacity of the platform and the safety coefficient of key parts such as an arm. Due to the reduced mass and shrunk volume, more functional arrangements can be increased. In addition, the valve body is directly and integrally formed by the additive manufacturing technology, the technical problems of cumbersome clamping, difficult form and position tolerance control, high requirement on roughness and the like due to pretreatment, machining, deburring, cleaning and the like in the traditional machining process are avoided.

The additive manufacturing method may include, but is not limited to a metal 3D printing method, such as selective laser melting (SLM). For the valve body of the integrated valve directly manufactured by the SLM process, the compactness up to 99.6 percent can be achieved, the defects such as air hole, sand hole and interlayer caused by the traditional manufacturing method are effectively reduced, and the qualification rate and use safety of products are effectively ensured.

In some other embodiments, other additive manufacturing methods may be used. After additive manufacturing is achieved, the assembling position can be subjected to finish machining, for example, tapping thread of the pipeline port of the internal flow channel.

For the flow channel subjected to the transition process according to the B-spline curve, the metal 3D printing method can reduce a large number of process hole structures required for the traditional design and manufacturing, effectively solve the technical problem of large pressure loss in the traditional design, effectively reduce the leakage risk in the use process of the valve body, and greatly reduce the pressure loss.

Referring to the method embodiment for manufacturing the valve body of the integrated valve, embodiments of the present disclosure further provide an integrated valve, including a valve body 30. The valve body 30 is manufactured by the method of any one of the above embodiments.

Referring to FIGS. 3 to 6, in some embodiments, the valve body 30 includes: an external shell 31, a work structure 32 of an internal flow channel structure, work structures 33 of respective mounting structures matched with external devices, and an internal supporting table 34. Here, the external shell 31, the work structure 32 of the internal flow channel structure, the work structures 33 of respective mounting structures matched with the external devices, internal and the supporting table 34 respectively correspond to the external shell, the work structure of the internal flow channel structure, the work structures of respective mounting structures matched with the external devices, and the internal supporting table in the valve model in the above design method embodiment. These structures are manufactured by an additive manufacturing method.

The work structure 32 of the internal flow channel structure is at least partially arranged in the external shell 31, and is fixedly connected to the external shell 31. The work structure 33 of respective mounting structures matched with the external device is at least partially arranged in the external shell 31, and is fixedly connected to the external shell 31. The internal supporting table 34 is arranged in the external shell 31, and is fixedly connected to at least part of the work structures 33 of respective mounting structures, the external shell 31, and at least part of the work structure 32 of the internal flow channel structure.

In some embodiments, the valve body 30 further includes a reinforcing rib 35. The reinforcing rib 35 is connected to at least one of the work structures 33 of respective mounting structures, the external shell 31, and the work structure 32 of the internal flow channel structure.

So far, embodiments of the present disclosure have been described in detail. To avoid obscuring the concepts of the present disclosure, some details known in the art are not described. Those skilled in the art may fully understand how to implement the technical solution disclosed herein according to the above description.

Although some specific embodiments of the present disclosure have been illustrated in detail through the examples, those skilled in the art should understand that the above examples are merely for illustration, but not intended to limit the scope of the present disclosure. Those skilled in the art should understand that the above embodiments may be modified or part of technical features may be equivalently replaced without departing from the scope and spirit of the present disclosure. The scope of the present disclosure is defined by the appended claims.

1. A method for designing a valve body of an integrated valve, comprising:
determining an internal flow channel structure of a valve body model of the integrated valve according to a hydraulic function implemented by the integrated valve;
according to a position and a connection mode of respective external devices connected to the integrated valve, determining a position and a size of respective mounting structures, matched with the external devices, in the valve body model;
determining a work structure of the valve body model according to the internal flow channel structure, and the position and the size of respective mounting structures;
determining an internal connection plane of the valve body model according to center lines of respective flow channels in the internal flow channel structure, and determining an internal supporting table for supporting the work structure according to the internal connection plane; and
determining an external shell of the valve body model, and connecting the external shell with the work structure and the internal supporting table.

2. The method according to claim 1, further comprising:
when determining the internal flow channel structure, performing transition process on the center lines of respective flow channels in the internal flow channel structure according to a B-spline curve.

3. The method according to claim 1, wherein the step of determining a work structure of the valve body model according to the internal flow channel structure, and the position and the size of respective mounting structures comprises:
according to the internal flow channel structure, and the position and the size of respective mounting structures, setting a preset thickness for the internal flow channel structure and respective mounting structures in the valve body model to form the work structure of the valve body model.

4. The method according to claim 3, wherein the step of forming the work structure of the valve body model comprises:
keeping a bore diameter of flow channels unchanged and setting a preset thickness for the internal flow channel structure, to form a work structure of the internal flow channel structure.

5. The method according to claim 3, wherein the step of according to a position and a connection mode of respective external devices connected to the integrated valve, determining a position and a size of respective mounting structures matched with the external devices in the valve body model comprises at least one of the followings:
determining a position and a size of a valve body mounting and fixing hole in the valve body model according to a mounting position and mounting mode of the integrated valve;
determining a position and a size of a shaft coupler mounting and fixing surface on the valve body model according to a connection position and size of a valve body center of the integrated valve and a shaft coupler;
determining a position and a size of a motor mounting and fixing hole in the valve body model according to a connection position and size of the valve body of the integrated valve and a motor;
determining a position and a size of a pump mounting and fixing hole in the valve body model according to a connection position and size of the valve body of the integrated valve and a pump;
obtaining a position and a size of an oil tank mounting and fixing hole in the valve body model according to a connection position and size of the valve body of the integrated valve and an oil tank; and
obtaining positions and sizes of connecting plug-ins and respective ports in the valve body model according to positions of connecting plug-ins of the valve body of the integrated valve and ports of the connecting plug-ins.

6. The method according to claim 5, wherein the step of forming the work structure of the valve body model comprises at least one of the followings:
keeping a bore diameter of the valve body mounting and fixing hole unchanged and setting a preset thickness for the valve body mounting and fixing hole, to form a work structure of the valve body mounting and fixing hole;
keeping a connection position and size of the shaft coupler mounting and fixing surface unchanged and setting a preset thickness for the shaft coupler mounting and fixing surface, to form a work structure of the shaft coupler mounting and fixing surface;
keeping a bore diameter of the motor mounting and fixing hole unchanged and setting a preset thickness for the motor mounting and fixing hole, to form a work structure of the motor mounting and fixing hole;
keeping a bore diameter of the pump mounting and fixing hole unchanged and setting a preset thickness for the pump mounting and fixing hole, to form a work structure of the pump mounting and fixing hole;
keeping a bore diameter of the oil tank mounting and fixing hole unchanged and setting a preset thickness for the oil tank mounting and fixing hole, to form a work structure of the oil tank mounting and fixing hole; and
keeping a connection position and size of the connecting plug-ins unchanged and setting a preset thickness for ports of the connecting plug-ins, to form a work structure of the connecting plug-ins and the ports of the connecting plug-ins.

7. The method according to claim 1, wherein the step of determining an internal connection plane of the valve body model according to center lines of respective flow channels in the internal flow channel structure comprises:
setting a plane in which most center lines of the flow channels are distributed as the internal connection plane.

8. The design method according to claim 7, wherein the step of determining an internal supporting table for supporting the work structure according to the internal connection plane comprises:
setting a preset thickness for the internal connection plane to form the internal supporting table, and fixedly connecting the internal supporting table with parts, located on two sides of the internal connection plane, of the work structure.

9. The method according to claim 1, further comprising:
when determining the external shell, arranging a lattice structure or a crystal lattice structure on a local position of the external shell.

10. The method according to claim 1, further comprising:
after forming the work structure, according to a protruding length or a protruding angle of a cantilever part of the work structure relative to the external shell, arranging a reinforcing rib on the cantilever part.

11. The method according to claim 1, further comprising:
performing finite element simulation and verification on the valve body model, and performing iteratively optimization on a stress concentration area of the valve body model.

12. The method according to claim 1, further comprising:
setting identification information on a surface of the valve body model.

13. A method for manufacturing a valve body of an integrated valve, comprising:
obtaining a valve body model designed by the method according to claim 1; and
machining and manufacturing the valve body model by an additive manufacturing method to form the valve body of the integrated valve.

14. An integrated valve, comprising:
a valve body, manufactured by the method according to claim 13.

15. The integrated valve according to claim 14, wherein the valve body comprises:
an external shell;
a work structure of an internal flow channel structure, at least partially arranged in the external shell and fixedly connected to the external shell;
work structures of respective mounting structures matched with the external devices, at least partially arranged in the external shell and fixedly connected to the external shell; and
an internal supporting table, arranged in the external shell, and fixedly connected to at least part of the work structures of respective mounting structures, the external shell and at least part of the work structure of the internal flow channel structure.

16. The integrated valve according to claim 15, wherein the valve body further comprises:
a reinforcing rib, connected to at least one of the work structures of respective mounting structures, the external shell and the work structure of the internal flow channel structure.
